(19) United States
(12) Patent Application Publication
(10) Pub. No.: US 2007/0275502 A1
(43) Pub. Date: Nov. 29, 2007

(54) Air cavity wafer level packaging assembly and method

(76) Inventors: Stephen George, Cambridge (CA); Galina Briskin, Waterloo (CA); Kenneth Yee Ching Koo, Richmond Hill (CA); Igor Genrikh Iourievitch, Kitchener (CA); Karim Nazarali, Mississauga (CA)

Correspondence Address: BERESKIN AND PARR, 40 KING STREET WEST, BOX 401, TORONTO, ON, M5H 3Y2, US

(21) Appl. No.: 11/441,011

(22) Filed: May 26, 2006

(51) Int. Cl. H01L 21/00

(52) U.S. Cl. 438/106

(57) ABSTRACT

A wafer level packaging method and assembly for packaging a wafer segment having active and inactive areas. A sacrificial layer is provided over the wafer segment. Then the sacrificial layer is modified to create a sacrificial structure having sacrificial layer openings which expose inactive areas. A cover layer is then deposited over the sacrificial structure such that the cover layer encloses the sacrificial structure and fills the sacrificial layer openings. The cover layer is modified to create a cover structure having cover layer openings that expose an inactive area of the wafer segment and through which the sacrificial structure can be removed. The sacrificial structure is removed and then enclosed with a sealing layer such that the sealing layer fills the cover layer openings in the cover structure. The cover structure and the sealing layer form the packaging assembly for the wafer segment.

### FIELD

This invention relates to wafer level packaging technology, and more particularly, to a wafer level packaging assembly and method.

### BACKGROUND

The packages of some electromechanical devices, such as surface acoustic wave (SAW) devices and micro electromechanical systems (MEMS), are required to provide air cavities above certain microstructures of the device. For example, a SAW device requires an air cavity above each of its transducer elements for the effective propagation of the surface acoustic waves that are being measured.

Common methods for producing air cavity packaging for micromechanical or electromechanical devices, such as ceramic packaging, create a package that is relatively large, costly, and difficult to produce in high volumes.

A recent production method has been developed that packages structures at the wafer level. However, there are a number of aspects of wafer level packaging that can be improved. There remains a need for wafer level packaging to be able to create multiple sealed air cavities. It is also desirable to be able to create reliable and robust wafer level packaging, which is compatible with injection molding and other manufacturing processes. Moreover, there is a need for cost effective, and easily produced wafer level packaging.

Increasingly, SAW filters are being used in cell phones. Therefore, there is especially a need in this industry to minimize the size and cost of the filters. At the same time, the cell phone industry requires SAW devices to filter increasingly large signals. Thus, there is a need for wafer level packaging that can be used in large signal and high power applications.

### SUMMARY

The embodiments described herein provide in one aspect, a method for packaging a wafer segment within a packaging assembly, wherein the wafer segment has active and inactive areas, the method comprising:
(a) providing a sacrificial layer over the active and inactive areas of the wafer segment;
(b) modifying the sacrificial layer to create a sacrificial structure, wherein the sacrificial structure includes at least one sacrificial layer opening which exposes an inactive area of the wafer segment;
(c) depositing a cover layer over the sacrificial structure, wherein the cover layer encloses the sacrificial structure and fills the at least one sacrificial layer opening;
(d) modifying the cover layer to create a cover structure, wherein the cover structure has at least one cover layer opening, which exposes an inactive area of the wafer segment, and wherein the sacrificial structure can be removed through the at least one cover layer opening;
(e) removing the sacrificial structure; and
(f) enclosing the cover structure with a sealing layer, wherein the sealing layer fills the at least one cover layer opening in the cover structure and wherein the cover structure and the sealing layer form the packaging assembly for the wafer segment.

The embodiments described herein provide in another aspect, wafer level packaging assembly for packaging a wafer segment, wherein the wafer segment has active and inactive areas, the assembly comprising:
(a) a cover layer positioned over the wafer segment, said cover layer having at least one cover layer support element and at least one cover layer opening; and
(b) a sealing layer having at least one sealing layer support element that fills one of the at least one cover layer opening such that the cover structure, the cover layer support element, the sealing layer and the sealing layer support element together define at least one sealed air cavity formed above at least one active area of the wafer segment.

Further aspects and advantages of the embodiments described herein will appear from the following description taken together with the accompanying drawings.

### BRIEF DESCRIPTION OF THE DRAWINGS

For a better understanding of the embodiments described herein and to show more clearly how they may be carried into effect, reference will now be made, by way of example only, to the accompanying drawings which show at least one exemplary embodiment, and in which:

FIG. 1 is a flowchart depicting an embodiment of a general wafer level packaging method for packaging a device on a wafer;

FIG. 2A is a top view of a wafer segment consisting of an unsealed surface acoustic wave (SAW) device mounted on the surface of a wafer substrate;

FIG. 2B is a cross-sectional view of the structure of FIG. 2A taken along the line 2B-2B;

FIG. 3A is a top view of the structure of FIGS. 2A and 2B with a first sacrificial sublayer deposited on top of its surface;

FIG. 3B is a cross-sectional view of the structure of FIG. 3A taken along the line 3B-3B;

FIG. 4A is a top view of the structure of FIGS. 3A and 3B after a second sacrificial sublayer is deposited on top of the first sacrificial sublayer;

FIG. 4B is a cross-sectional view of the structure of FIG. 4A taken along the line 4B-4B;

FIG. 5A is a top view of a sacrificial mask positioned over the structure of FIGS. 4A and 4B;

FIG. 5B is a cross-sectional view of the structure of FIG. 5A taken along the line 5B-5B, illustrating the exposure of the sacrificial sublayers of the structure of FIG. 5A to light through the sacrificial mask;

FIG. 6A is a top view of the structure of FIG. 5A after the light exposed portions of the sacrificial layer of the structure of FIGS. 5A and 5B have been dissolved in a solvent and washed away;

FIG. 6B is a cross-sectional view of the structure of FIG. 6A taken along the line 6B-6B, illustrating the resulting sacrificial structure formed after the exposed portions of the sacrificial layer have been dissolved in the solvent and washed away;

FIG. 7A is a top view of the structure of FIGS. 6A and 6B, after the application of a cover layer;

FIG. 7B is a cross-sectional view of the structure of FIG. 7A taken along the line 7B-7B, after the application of cover layer;

FIG. 8A is a top view of the structure of FIGS. 7A and 7B during exposure of the cover layer using a cover layer mask;

FIG. 8B is a cross-sectional view of the structure of FIG. 8A taken along the line 8B-8B, during exposure of the cover layer using a cover layer mask;

FIG. 9A is a top view of the resulting cover structure of FIGS. 8A and 8B which is formed after the unexposed portions of the cover layer have been dissolved in the solvent and washed away;

FIG. 9B is a cross-sectional view of the resulting cover structure of FIG. 9A taken along the line 9B-9B, which is formed after the unexposed portions of the cover layer and the sacrificial structure have been dissolved and washed away;

FIG. 10A is a top view of the structure of FIGS. 9A and 9B after application of a sealing layer;

FIG. 10B is a cross-sectional view of the structure of FIG. 10A taken along the line 10B-10B, after the application of sealing layer;

FIG. 11A is a top view of another exemplary embodiment of the structure of FIG. 10A;

FIG. 11B is a cross-sectional view of the structure of FIG. 11A taken along the line 11B-11B;

FIG. 12A is a top view of the structure of FIGS. 10A and 10B after the formation of contact openings; and

FIG. 12B is cross-sectional view of the structure of FIG. 12A taken along the line 12B-12B.

It will be appreciated that for simplicity and clarity of illustration, elements shown in the figures have not necessary been drawn to scale. For example, the dimensions of some of the elements may be exaggerated relative to other elements for clarity.

### DETAILED DESCRIPTION

It will be appreciated that for simplicity and clarity of illustration, where considered appropriate, reference numerals may be repeated among the figures to indicate corresponding or analogous elements or steps. In addition, numerous specific details are set forth in order to provide a thorough understanding of the exemplary embodiments described herein. However, it will be understood by those of ordinary skill in the art that the embodiments described herein may be practiced without these specific details. In other instances, well-known methods, procedures and components have not been described in detail so as not to obscure the embodiments described herein. Furthermore, this description is not to be considered as limiting the scope of the embodiments described herein in any way, but rather as merely describing the implementation of the various embodiments described herein.

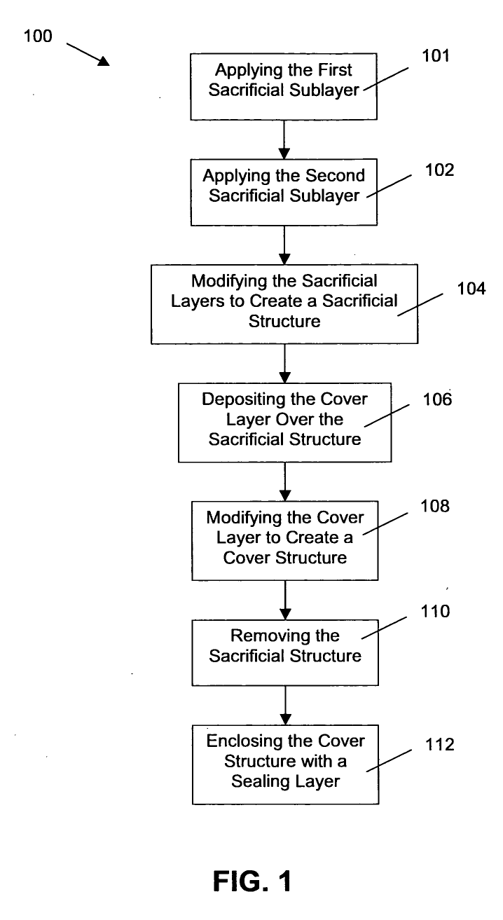

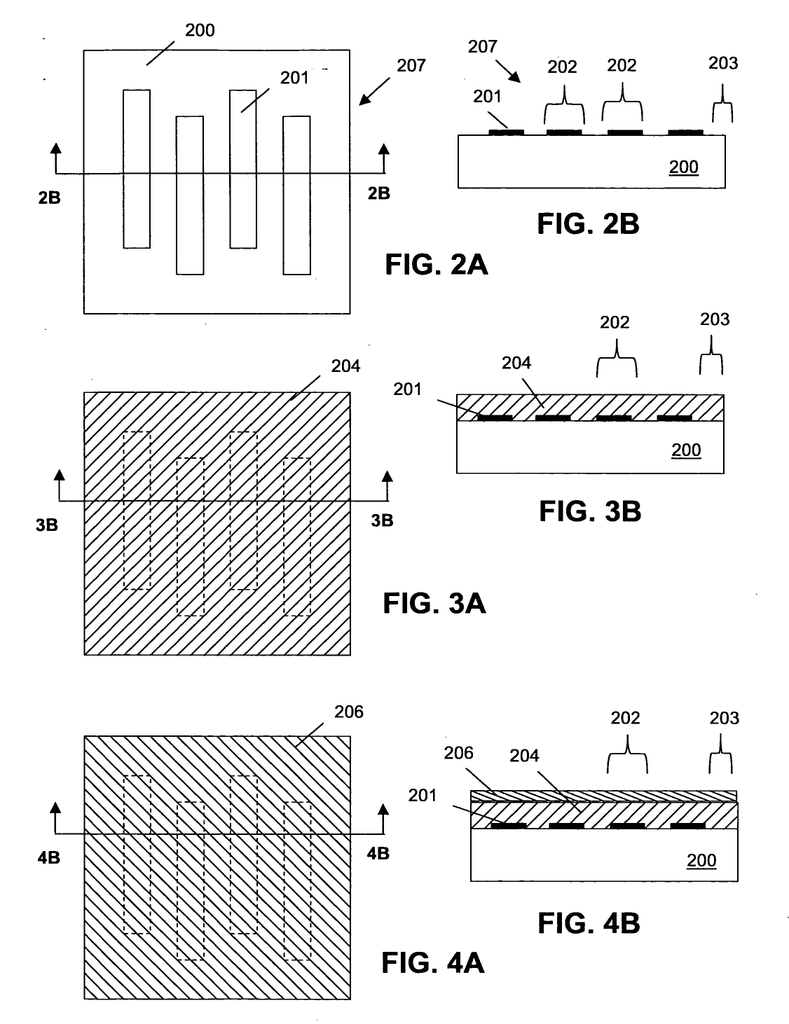

Reference is first made to FIGS. 1, 2A and 2B. FIG. 1 is a flowchart depicting an embodiment of the wafer level packaging method 100 for packaging one or more device elements 201 formed on the top surface of a wafer substrate segment 200 and contains seven general processing stages as will be described in detail. The device elements 201 can be associated with any micromechanical or electromechanical device, such as a surface acoustic wave (SAW) devices or micro electromechanical systems (MEMS).

FIGS. 2A and 2B are top and cross-sectional views, respectively, of a wafer segment 207 that consists of a number of micromechanical or electromechanical device elements 201 formed on a wafer substrate segment 200. FIG. 2B is a cross-sectional view of the wafer segment 207 taken along the line 2B-2B.

The wafer segment 207 has active areas 202 (FIG. 2B) and inactive areas 203. The active areas 202 contain the micromechanical or electromechanical device elements 201 that will be protected and enclosed by the wafer level packaging assembly formed by application of the packaging method 100. The inactive areas 203 do not contain any device elements 201 and instead are used to locate support elements for the packaging assembly that results from the packaging method as will be discussed. Inactive areas 203 may also contain passive elements such as conventionally known busbars or interconnect pads.

Specifically, the exemplary wafer substrate segment 200 (shown in FIGS. 2A to 10B) that is used to illustrate the processing stages of the packaging method 100 has four device elements 201 formed on its surface. Accordingly, wafer segment 207 contains four active areas 202. The remainder of the surface areas of the wafer segment 207 are considered to be inactive areas 203. It should be understood that the packaging method 100 can be applied to a wafer substrate segment 200 having any number of device elements 201, active areas 202 and/or inactive areas 203 and that the wafer substrate segment 200 can be a variety of shapes and configurations, depending on the type and configuration of device elements 201 to be packaged.

The wafer substrate segment 200 can be made of lithium tantalate or another material with suitable electrical and mechanical properties, such as a silicon-based material. Also, typically, the complete wafer substrate is circular and has a diameter that allows it to be handled manageably during the processing stages of the packaging method 100.

The exemplary wafer segment 207 is shown in association with an exemplary surface acoustic wave (SAW) device. This particular exemplary SAW device has four rectangular transducer device elements 201 and accordingly the wafer segment 207 contains four active areas 202 which are arranged in a manner that is conducive to surface acoustic wave propagation. The transducer device elements 201 of the exemplary SAW device are conventionally made of deposited aluminum, aluminum alloy, or multiple metal layers, are patterned by conventional manufacturing processes, and are typically electrically interconnected using metal interconnects (not shown).

Typically, numerous SAW devices are manufactured on a single wafer substrate. For example, a four-inch wafer can hold up to 6000 SAW devices. Accordingly, it should be understood that while the wafer level packaging method 100 is presently discussed in relation to this particular exemplary segment 200 of a wafer substrate with four unconnected device elements 201, the basic principles of the packaging method 100 could be applied to an entire wafer substrate and/or in association with a plurality of device elements 201, electrically connected or otherwise.

Reference is now made to FIGS. 1, 3A and 3B. The first processing stage (101) of the packaging method 100 consists of depositing a first sacrificial sublayer 204 over the active areas 202 and inactive areas 203 of the wafer segment 207 of FIG. 2B, discussed above.

FIGS. 3A and 3B provide top and cross-sectional views, respectively, of the structure which results from depositing a first sacrificial sublayer 204 on top of the wafer segment 207, namely the wafer substrate segment 200 and the device elements 201. Specifically, FIG. 3B illustrates the cross-sectional view of the structure taken along the line 3B-3B shown in FIG. 4A. As shown, after deposit, the first sacrificial sublayer 204 covers the entire top surface of the wafer substrate segment 200 and device elements 201, such that both active areas 202 and inactive areas 203 of wafer segment 207 are covered.

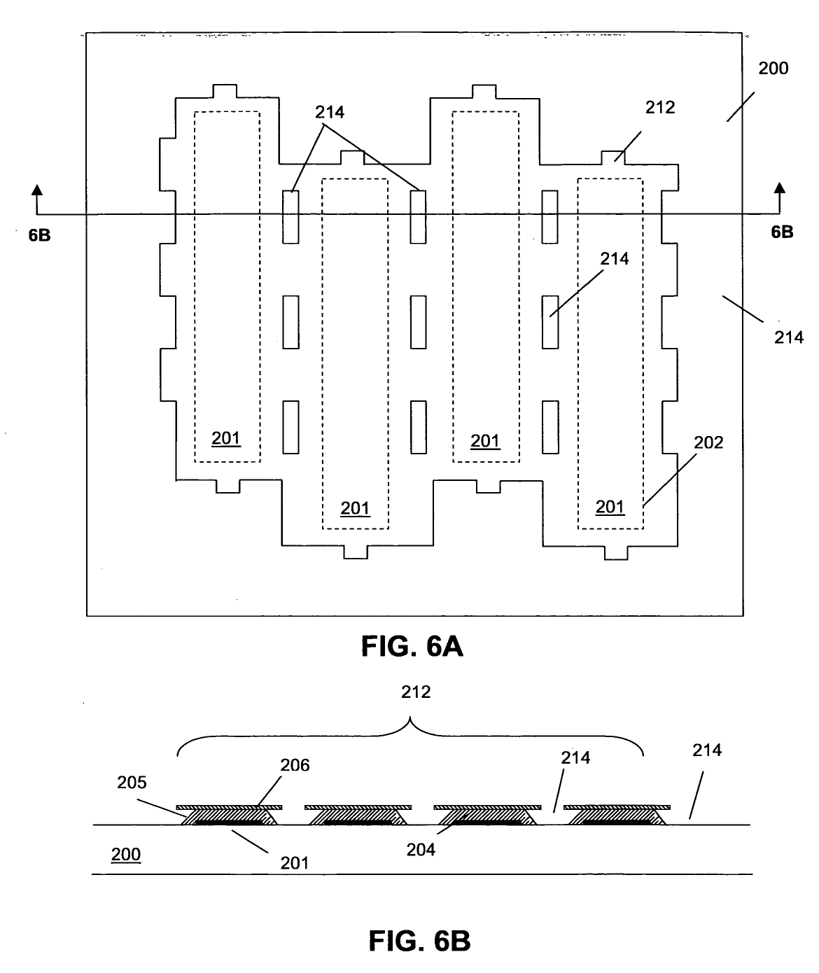

The first sacrificial sublayer 204 is preferably a polymer release layer (e.g. PiRL™, made by Brewer Science, Inc. of Missouri, U.S.A.). There are many advantages to the use of a material such as PiRL™ in the present packaging method 100. First, a material such as PiRL™ can be applied quickly to create a relatively thick sacrificial layer which, when removed at a later processing stage will allow for correspondingly raised air cavities. Preferably, the first sacrificial sublayer 204 has an applied thickness in the range of 5 to 15 microns, for example 8 microns. In addition, a material like PiRL™ is capable of being processed to create sacrificial sublayer openings 214 (FIG. 6B) that have tapered walls, the advantages of which will be described in detail below.

However, it should be understood that the first sacrificial sublayer 204 could be any other suitable material, such as a polymer, that is chemically compatible with the material comprising the device elements 201 of the device, such as deposited aluminum. In addition, the selected material for the first sacrificial sublayer 204 must also be dissolvable by a solvent (for use in a later processing stage) that is itself chemically compatible with the active areas 202 of the wafer substrate segment 200. It should be understood that, as conventionally known, a material or solvent is considered to be chemically compatible with another material when it does not etch or degrade the other material or degrade polymers processed during earlier operations.

Now referring to FIGS. 1, 4A and 4B, the second processing stage (102) of the packaging method 100 consists of depositing a second sacrificial sublayer 206 over the first sacrificial sublayer 204. The second sacrificial sublayer 206 can be made out of any suitable photo resist material. Also, the second sacrificial sublayer 206 has an applied thickness that is suitable for resolution of the required feature sizes and is preferably in the range of 0.5 to 5 microns, for example 0.8 microns.

Both sacrificial sublayers 204 and 206 will be removed at a later processing stage and will be replaced by an air cavity. Due to the relative preferred thickness ratio between the first and second sacrificial sublayers 204 and 206, it should be understood that the first sacrificial sublayer 204 is the predominate determining factor in the final thickness of the combined first and second sacrificial layer 204 and 206 and accordingly, is also the predominate determining factor in the height of the resulting air cavities produced by packaging method 100.

FIGS. 4A and 4B illustrate top and cross-sectional views, respectively, of the unpackaged wafer substrate segment 207 after a second sacrificial sublayer 206 is deposited over the first sacrificial sublayer 204. Specifically, FIG. 4B is a cross-sectional view of the structure along the line 4B-4B shown in FIG. 4A. The second sacrificial sublayer 206 covers the entire first sacrificial sublayer 204 and is typically a photosensitive polymer, such as a positive photo resist. Any suitable photosensitive polymer that is chemically compatible with the first sacrificial sublayer 204 can be used as long as the solvent that is used to eventually dissolve the second sacrificial layer 206 does not adversely affect the first sacrificial sublayer 204 or the active areas 202 of the device, as will be discussed in further detail below. In later process steps, the second sacrificial sublayer 206 is patterned and developed to create the desired sacrificial structure 212 (FIG. 6B).

Now referring to FIGS. 1, 5A, 5B, 6A and 6B, the third processing stage (103) of the packaging method 100 involves modifying the first and second sacrificial sublayers 204 and 206 to create a sacrificial structure 212 (FIG. 6B). Preferably, the first and second sacrificial sublayers 204 and 206 are photo-lithographically patterned and developed to create a number of sacrificial layer openings 214 (FIG. 6B). These sacrificial layer openings 214 will then expose inactive areas of the wafer substrate segment 200 as will be described.

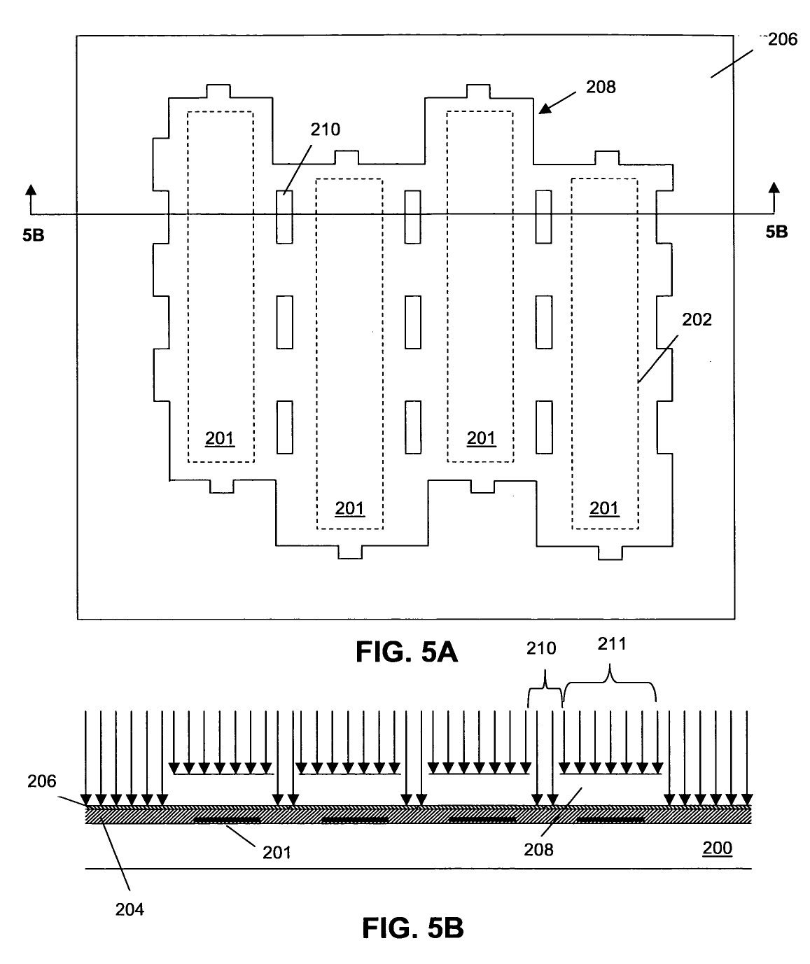

FIGS. 5A and 5B show a top and cross-sectional view, respectively, illustrating the light exposure of the first and second sacrificial sublayers 204 and 206 through a sacrificial mask 208 (FIG. 5A). As indicated, FIG. 5B is a cross-sectional view of the structure taken along line 5B-5B shown in FIG. 5A.

The sacrificial mask 208 is designed to prevent light being applied to the top surface of the second sacrificial sublayer 206 from certain sections of the second sacrificial sublayer 206. As conventionally known, masks can be made of a variety of materials such as glass with chrome positioned on the underside of the glass to block the light. The second sacrificial sublayer 206 is a positive photo-resist (as opposed to a negative photo-resist). Thus, only the areas of the second sacrificial sublayer 206 that are exposed to the applied light will become susceptible to the solvent used in the next development step. This process is commonly referred to as photo-lithographical patterning.

As shown, holes 210 in the mask 208 are used to allow light to pass through to the second sacrificial sublayer 206 in places that correspond to the sections of the first and second sacrificial layers 204 and 206 that are intended to be dissolved. The covered areas 211 of the second sacrificial sublayer 206, that is those which correspond to the solid areas of the mask 208, are not exposed. The light exposure is performed at a wavelength at which the second sacrificial sublayer 206 is sensitive. It will be appreciated by one of skill in the art, that it is not necessary for the first and second sacrificial sublayers 204 and 206 be present in sections where the sacrificial sublayers 204 and 206 are to be removed.

FIGS. 6A and 6B show top and cross-sectional views, respectively, of the resulting sacrificial structure 212 which is formed after the exposed portions of the first and second sacrificial sublayers 204 and 206 have been dissolved and washed away by an applied solvent, also referred to as a developing solution. FIG. 6B is a cross-sectional view of the structure taken along the line 6B-6B shown in FIG. 6A.

As shown in FIG. 6A, the sacrificial structure 212 covers the active areas 202 of the wafer segment 207. Also, the sacrificial structure 212 includes a number of sacrificial sublayer openings 214 that were formed by the previous processing step. These sacrificial sublayer openings 214 correspond to the areas of the second sacrificial sublayer 206 that were exposed to light through holes 210 in the mask 208. The configuration of the photo-lithographical pattern and resulting sacrificial sublayer openings 214 create the sacrificial structure 212 that acts as a mold for the cover layer 216, which is applied in the next process step.

The development of the first and second sacrificial sublayers 204 and 206 discussed above leaves the remaining parts of the first sacrificial sublayer 204 with tapered sidewalls 205 and sections of the second sacrificial sublayer 206 overhanging the tapered sidewalls 205 as shown in FIG. 6B. The material properties of the two different first and second sacrificial sublayers 204 and 206 affect their relative susceptibility to the applied solvent.

Preferably, the second sacrificial sublayer 206 is less susceptible to the applied solvent than the first sacrificial sublayer 204. Consequently, the sloped walls of the first sacrificial sublayer 204 as shown in FIG. 6 are formed as the applied solvent dissolves the first sacrificial sublayer 204 from above and since the solvent is applied to the top part of the wall for a greater duration of time than the bottom part of the wall. Various factors including the dimensions of the mask 208, the material susceptibility of the first sacrificial sublayer 204, and processing parameters such as the exposure time, developing time, temperature and the degree of agitation of the applied solvent all influence the specific configuration of the sloped walls of the remaining first sacrificial sublayer 204 as shown in FIG. 6B.

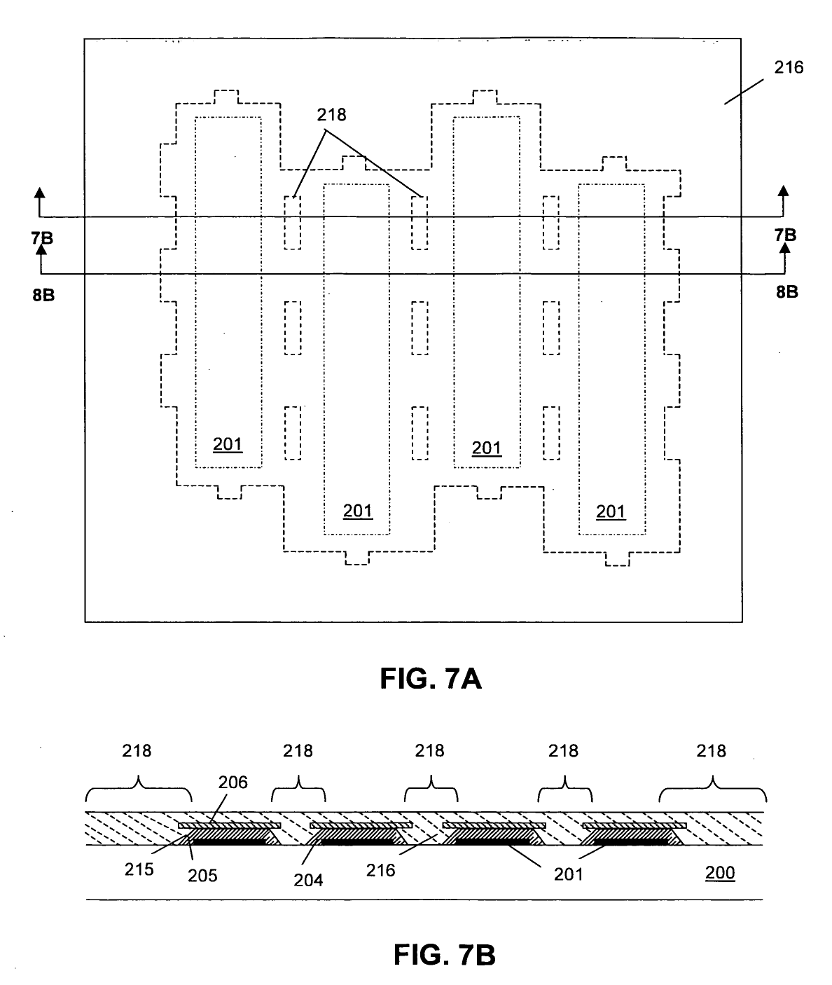

The resulting tapered sidewalls 205 of the first sacrificial sublayer 204 allow the active areas 202 of the wafer segment 207 to be placed more closely together and give the subsequent cover layer 216 (FIG. 7B) structural advantages, which will be further described in the discussion of FIGS. 7A and 7B.

Now referring to FIGS. 1, 7A and 7B, the fourth processing stage (104) of the packaging method 100 entails depositing a cover layer 216 over the sacrificial structure 212 (FIG. 6B) created during processing stage (103). The cover layer 216 can be made from any suitable photo resist material (e.g. SU-8™ manufactured by MicroChem, Inc. of Massachusetts, U.S.A) that is insoluble to the solvent used to dissolve the sacrificial structure 212 in stage (106). The cover layer 216 encloses the sacrificial structure 212 and fills the sacrificial layer openings 214, thereby creating cover layer support elements 218 (FIG. 7B).

FIGS. 7A and 7B show a top and cross-sectional view of the structure of FIGS. 6A and 6B after the application of cover layer 216. Specifically, FIG. 7B is a cross-sectional view of the structure taken along the line 7B-7B shown in FIG. 7A.

When the cover layer 216 is applied over the sacrificial structure 212, the cover layer 216 fills the sacrificial sublayer openings 214 (FIG. 6B) to create cover layer support elements 218. The cover layer support elements 218 have tapered support walls 215 that are inverted from the tapered walls of the sacrificial sublayer openings 214, from which they were molded. Thus, the cross-sectional area of the cover layer support elements 218 at their top end is larger than the cross-sectional area at their bottom end. This is advantageous because this lessens the points of stress on the cover structure 217, thereby creating a more robust cover structure 217. Furthermore, the cover layer support elements 218 may be smaller, allowing the active areas 202 of the area to be placed more closely together. This, in turn, reduces the size of the overall packaged device.

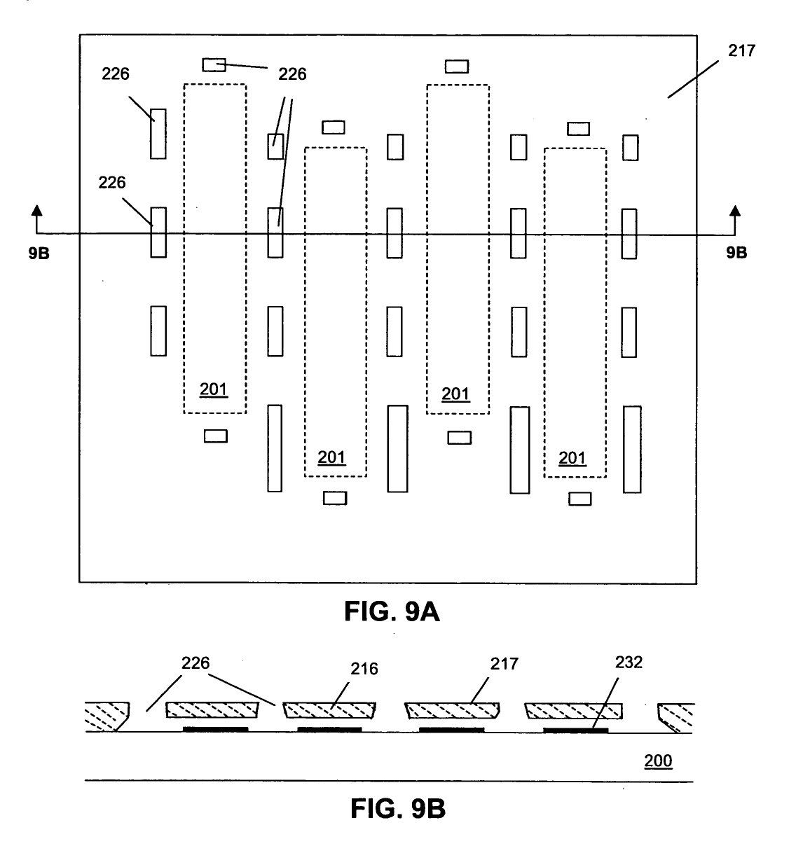

The cover layer 216 can be a layer of photo-resist, such as SU-8™ (made by MicroChem, Inc. of Massachusetts, U.S.A). The material SU-8™ is an epoxy-based negative photo resist that, when exposed, creates cross-linked portions that are insoluble to solvents or liquid developers. SU-8™ is an example of an appropriate material for the cover layer 216. Another suitable photo resist, or other material, could be used. Preferably, the cover layer 216 has an applied thickness in the range of 8 to 12 microns, for example 10 microns, that provides the cover layer with sufficient mechanical strength to withstand the application of the sealing layer 234, which will be described in detail below. Further, the thickness of the cover layer 216 affects the ability to resolve the openings 226 (FIG. 9B) as well as affecting the ability of the sealing layer 234 to seal the cover structure 217, which will be described in detail below.

In contrast to a positive photo resist (i.e. what the second sacrificial sublayer 206 is made from), the areas of the negative photo resist material of cover layer 216 that are shaded from light are removed and only the exposed parts become insoluble to solvents or liquid developers.

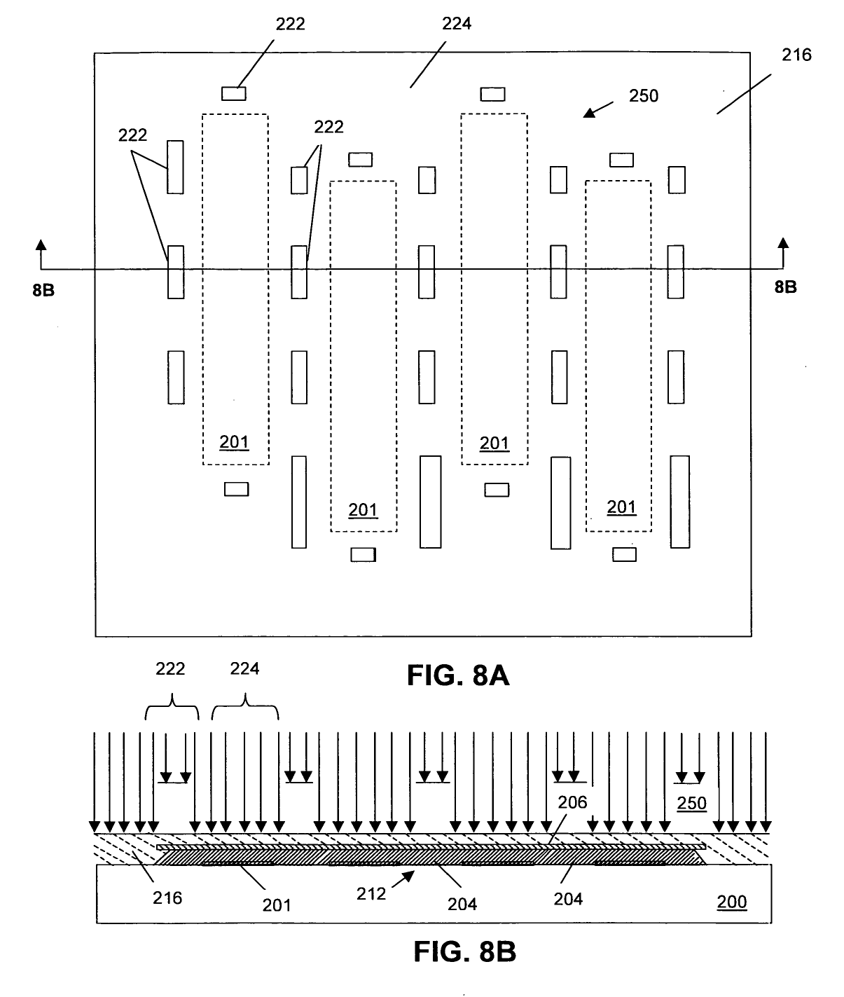

Referring now to FIGS. 1, 8A, and 8B, the fifth processing stage (105) of the packaging method 100 consists of modifying the cover layer 216 to create a cover structure 217 (FIG. 9B) having a number of cover layer openings 226 (FIG. 9B), that expose the sacrificial structure 212 (consisting of the patterned first and second sacrificial sublayers 204 and 206) underneath. In a preferred embodiment, the cover layer is photo-lithographically patterned and developed to create the cover layer openings 226.

FIG. 8A and 8B show top and cross-sectional views, respectively, illustrating the exposure of the cover layer 216 to light through the open areas 224 in the cover layer mask 250. The cover layer mask 250 is designed to prevent light from being exposed to various covered areas 222 of the cover layer 216 and is preferably made of similar materials as sacrificial mask 208 discussed above.

FIG. 8B shows a cross-sectional view illustrating in part the first and second sacrificial sublayers 204 and 206 taken along the line 8B-8B in FIG. 8A. It should be noted that this cross-sectional view is at a different position than the side-sectional view of FIG. 7B that was taken along the line 7B-7B as can be seen in FIG. 7A.

The cross-sectional view of the wafer segment 207 shown in FIG. 7B shows four portions of the first and second sacrificial sublayers 204 and 206 separated by three cover layer support elements 218 that were formed by filing the sacrificial sublayer openings 214 with the cover layer 216. In contrast, the cross-sectional view of the wafer segment 207 shown in FIG. 8B shows a continuous portion of the first and second sacrificial sublayers 204 and 206 since the cross-sectional view at 8B-8B does not traverse any cover layer support 218 (i.e. or previously formed sacrificial sublayer openings 214).

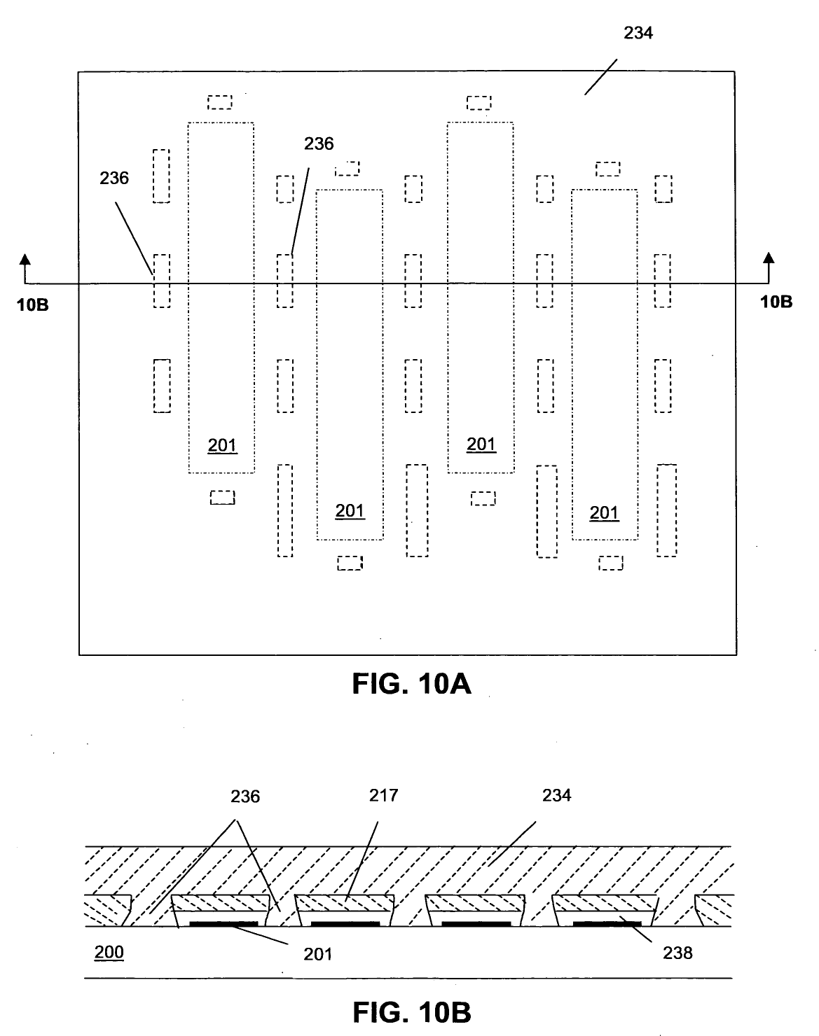

These two different side-sectional views mark a shift at the position within the wafer segment 207 at which the remaining side-sectional views illustrated in FIGS. 9B and 10B are taken. Acknowledgment of this shift is necessary to understand how the walls of the individual air cavities 238 (FIG. 10B) comprise both the sides of the cover layer support elements 218 (FIG. 7B) and the sides of the sealing layer support elements 236 (FIG. 10B).

As discussed above, in the exemplary embodiment, the cover layer 216 is a negative photo-resist. In contrast to a positive photo resist (i.e. used for the second sacrificial sublayer 206), the areas of the negative photo resist material of cover layer 216 that are protected from light exposure are removed and only the exposed areas become insoluble to solvents or liquid developers. Thus, the configuration of the cover layer mask 250 is opposite in manner to the configuration of the sacrificial mask 210. Accordingly, only the covered areas 222 of the cover layer 216 that are left unexposed to the light will become susceptible to the solvent that is applied after the cover structure 217 has been photo-lithographically patterned. The light exposure is performed at a wavelength where the cover layer 216 is sensitive.

Referring now to FIGS. 1, 9A and 9B, the sixth processing stage (106) of the packaging method 100 consists of the removal of the sacrificial structure 212 through the cover layer openings 226 formed during the previous fifth processing stage discussed above. As shown in FIG. 9B, the cover structure 217 remains in place over the wafer substrate 200, suspended above it, and is physically supported by both the intact exposed portions of the cover layer 216 or the remaining cover layer support elements 218 (shown best in FIG. 7B) and after the next processing stage, the cover layer support elements 236 (FIG. 10B).

Specifically, FIGS. 9A and 9B show top and cross-sectional views, respectively, of the resulting cover structure 217 formed after the unexposed portions of the cover layer 216 have been washed away. FIG. 9B is a cross-sectional view taken along the line 9B-9B in FIG. 9A. The cover structure 217 contains cover layer openings 226 in a pattern created by covered sections 222 of the cover layer mask 250 (FIG. 8A). As previously discussed, the configuration of the cover layer openings 226 determines the locations of the sealing layer support elements 236 which are created in the next process stage. Thus, the locations of the cover layer openings 226 are primarily determined by the arrangement of the active areas 102 and the corresponding cover layer support elements 218.

The developing solution that is used to wash away the unexposed portions of the cover layer 216 at least partially dissolves the remaining portions of the second sacrificial sublayer 206. A solvent is then used to dissolve the remaining portions of the second sacrificial sublayer 206 after the development of cover structure 217. Then, the same, or a different, solvent is used to dissolve the first sacrificial sublayer 204, depending on the chemistry of the sacrificial materials. As described above, the solvent that is used to dissolve the first sacrificial sublayer 204 must be chemically compatible with the active areas 202 of the device so that the first sacrificial sublayer 204 is removed without any degragation of the metallised device elements 201.

The cover structure 217 is processed in a conventional manner, including being hardened for strength. The cover structure 217 can also be cured for longer than the standard manufacturer's cure times to effectively further age harden the polymer. As described above, the potential failure of the cover structure 217 due to internal stress is reduced by the inverted profile of the cover layer support elements 218.

Referring to FIGS. 1, 10A and 10B, the seventh processing stage (107) of packaging method 100 consists of enclosing the cover structure 217 with a sealing layer 234. The sealing layer 234 fills the cover layer openings 226 in the cover structure 217 and flows onto the inactive areas 202 of the wafer segment 207, thereby creating sealing layer support elements 236.

FIGS. 10A and 10B show top and cross-sectional views after the application of the sealing layer 234 over the cover structure 217 of FIGS. 9A and 9B. The sealing layer 234 is a controlled-flow epoxy film that, when heated, enters a semi-liquid state and flows into and fills the cover layer openings 226 to create sealing layer support elements 236. Preferably, the sealing layer 234 has an applied thickness in the range of 10 to 100 microns, for example 30 microns.

When the sealing layer 234 flows into the cover layer openings 226, the sealing layer 234 also adheres to the inactive areas 203 of the surface of the wafer segment 207, creating a substantially hermetic seal. Before the application of the sealing layer 234, the wafer 200 may be placed in a target atmosphere or vacuum, to allow the air cavities 238 to be filled with a desired gas or vacuum. In conjunction with cover layer support elements 218, the sealing layer support elements 236 create individually sealed air cavities 238 above each active area 202 on the wafer 200.

As shown in FIG. 10B, four air cavities 238 are provided above the four active areas 202 of the wafer segment 207. As can be seen by considering the structures shown in FIGS. 7B, 8B, 9B and 10B, the side walls of each air cavity 238 are comprised of cover layer support elements 218 and sealing layer support elements 236. Also, as discussed above, the sealing layer support elements 236 adhere to the cover layer support elements 218 and the inactive areas 203 of the device, creating a substantially hermetic seal for each individual air cavity. Although not shown in the present figures, it is also possible to have interconnected air cavities by not filling cover layer openings 226 that create sealing layer support elements 236 between the air cavities 238.

The sealing layer 234 is processed so that it does not flow onto the active areas 202 of the wafer segment 207. The use of controlled-flow epoxy film as the sealing layer 234 allows the flow to be controlled more easily than other liquid polymer layers. In addition, controlled-flow epoxy film has the ability to fill large cover layer openings without flowing onto the active areas 202 of the wafer 200.

Larger cover layer openings 226 can be advantageous because they allows for rapid and more complete removal of the sacrificial structure 212. Also, the use of controlled-flow epoxy film as the sealing layer 234 allows for the positioning of cover layer openings 226 directly over the active areas 202, provided the size of the openings is small enough to prevent the flow onto the active areas 202. The viscosity of the epoxy film sealing layer 234 during processing can be accurately controlled to achieve both flow into larger cover layer openings 226 and to prevent flow into the smaller cover layer openings 226.

The manner in which the sacrificial structure 212 (FIGS. 6A and 6B) and the cover structure 217 (FIGS. 9A and 9B) are photo-lithographically patterned determines the configuration of their respective support elements. As a result, the final product packaging assembly can contain a single sealed air cavity or multiple individually sealed air cavities 238, depending on the configuration of the cover layer 216 and the sealing layer support elements 236. Further, the final result packaging assembly can contain multiple air cavities 238 that are interconnected and sealed as a group.

Sealing layer 234 provides the packaging assembly with protection against corrosion due to moisture and increases the long-term reliability. Further, the packaging assembly enables the packaged device to withstand soldering, plating, wire bonding, and other conventional manufacturing conditions. The inventors have determined in practice that the final packaged device assemblies display the quality of the seal through high-pressure liquid bombing tests. These final packaged device assemblies have also exhibited any degradation during long-term accelerated age testing, simulating 3000 hours of operation at 125° C.

By acting as part of the walls of the air cavity 238, the sealing layer support elements 236 also contribute to the structural support of the packaging assembly. In other words, the walls of each air cavity 238, which are comprised partially of sealing layer support elements 236, provide the structural strength required for a robust and reliable packaging assembly. Further, the sealing layer 234 is rendered rigid after curing. As a result, the packaging assembly is capable of overmolding and other manufacturing processes.

The thickness of the first and second sacrificial sublayers 204 and 206 determines the height of the air cavity 238 established over the active area 202. In turn, the height of the air cavity 238 is a major factor, which affects the performance of the device elements 201. The size of the air cavity 238 may also be a factor in the device's ability to dissipate heat and, therefore, the ability to be used in high power applications. Thus, the ability to control the thickness of the sacrificial layers is important. As discussed above, the preferred thickness range for the first sacrificial sublayer 204 is 5 to 15 microns (e.g. 8 microns) and the typical thickness range for the second sacrificial sublayer 206 is 0.5 to 5 microns (e.g. 0.8 microns).

It will be appreciated by those of skill in the art, that the sacrificial sublayers 204 and 206 could be replaced by a single layer of photosensitive polymer. However, in the preferred embodiment, two sacrificial sublayers 204 and 206 are used because if each sublayer 204 and 206 has a different susceptibility to the solvent used to create the sacrificial structure, then it is possible to create sublayer openings 214 that have tapered walls 205 as has been described.

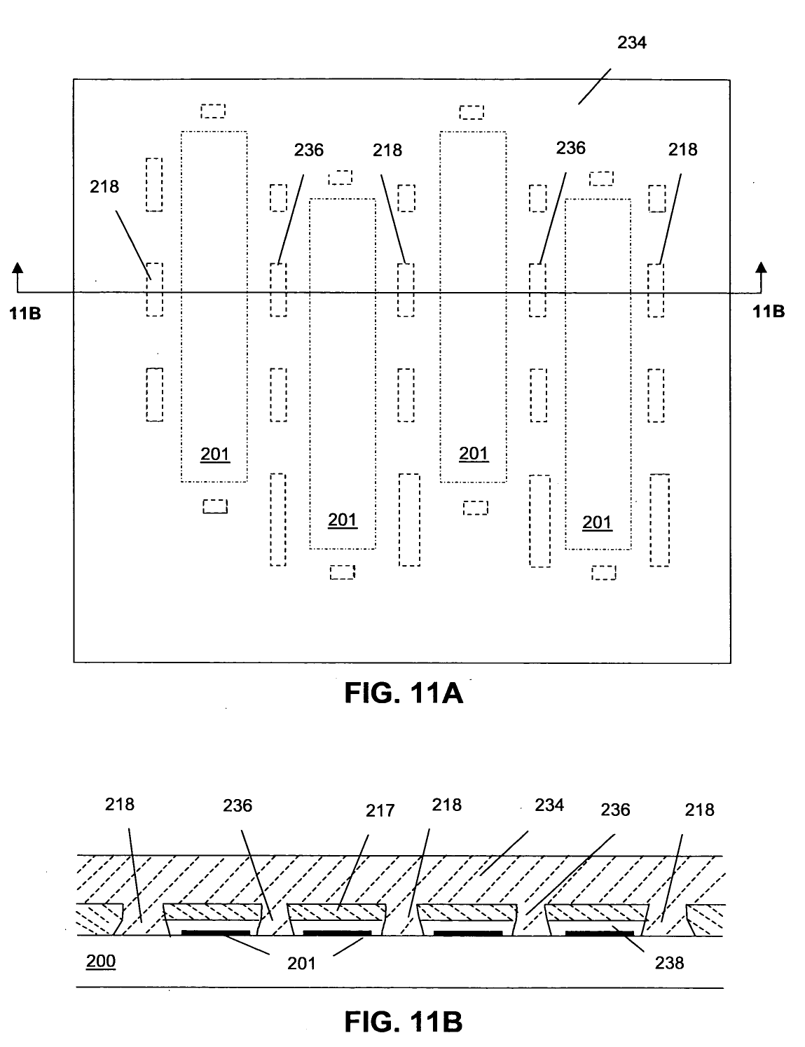

FIGS. 11A and 11B illustrate a cross-sectional view of a completed packaging assembly made in accordance with another exemplary embodiment of the packaging method 100. In this embodiment, the support elements of each air cavity 238 wall are offset. That is, the cover layer support elements 218 and sealing layer support elements 236 are offset, so that they alternate across the cross-section as shown in FIG. 11B. Since the cover layer support elements 218 and sealing layer support elements 236 are arranged in an alternating matter within the packaging assembly each sealed air cavity is enclosed by a cover layer support element on one side and a sealing layer support element on an opposite side. Accordingly, this configuration aids the removal of the sacrificial sublayers 204 and 206, which reduces the time the structural support of the packaging assembly is exposed to solvents.

The primary thermal dissipation means of a packaged SAW device is conduction through the wafer substrate 200. However, the creation of large air cavities 238 by the sealing layer 234 also significantly contributes to heat dissipation, and in particular, to the ability of the packaging assembly to be used in high power applications. With respect to SAW devices, the larger the surface area of the transducer elements 201 (i.e. active areas 202), the greater the ability is of the large air cavities 238 to dissipate heat. The present embodiment allows for larger individual air cavities 238 over larger active areas 202 because of the support provided by the combination of the cover layer support elements 218, the cover structure 217, the sealing layer 234, and the sealing layer support elements 236.

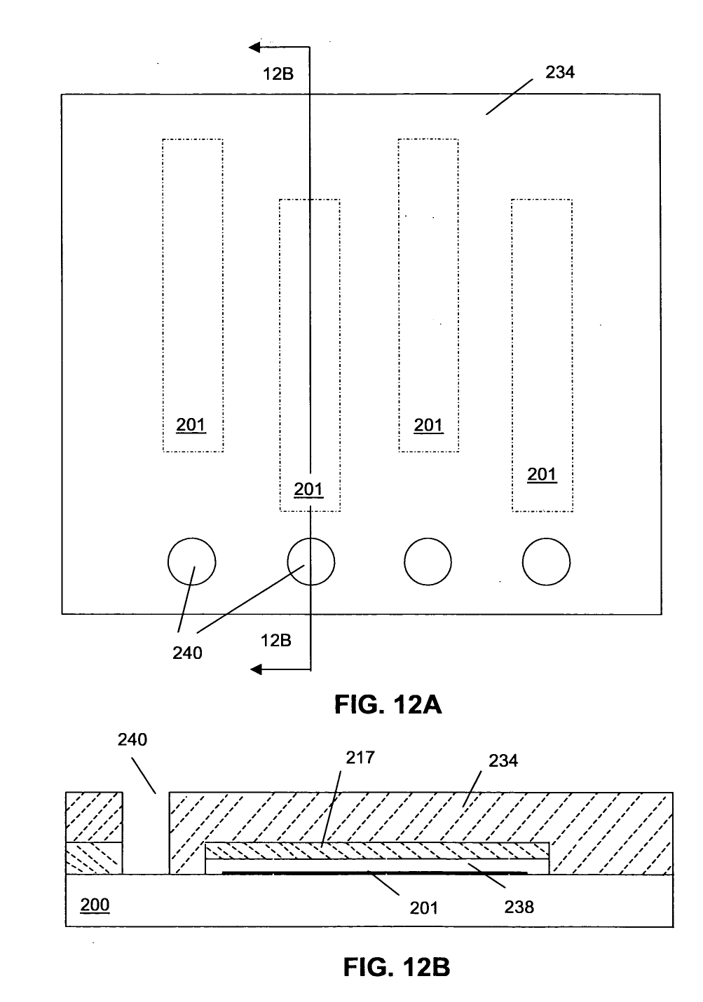

FIGS. 12A and 12B illustrate top and cross-sectional views of the completed packaging assembly, made in accordance with the exemplary embodiment of the packaging method 100, and also including four contact openings 240. Contact openings 240 are formed in the sealing layer 234 and cover layer 217 to expose inactive areas 203 of the wafer segment 207. The sealing layer 234 can be photoimageable, and can be patterned and developed in a conventional manner to create contact openings 240, as shown. Of course, it will be understood by one of skill in the art that the location and number of contact opening openings may vary.

Contact openings 240 can be used as solder ball resist areas, which are required for under bump metallization plating processes and can also enable UBM application without further photo resist layers. The thickness of the sealing layer 234 is selected such that screen-printed solder paste can be applied directly to the polymer surface and can be reflowed to create solder balls of controlled size. Alternatively, the contact openings 240 can be used for direct application of gold ballbond either intended for wirebond applications or gold bump flip-chip processing. The contact openings 240 are positioned to suite the board onto which the die is to be mounted and also to ensure mechanical rigidity. Additional and subsequent processing steps include the dicing of the packaging assembly wafer into individual device chips.

Accordingly, the wafer level packaging method 100 provides an effective and reliable wafer level packaging structure for device elements 201 formed on the top surface of a wafer substrate segment 200. Further, the wafer level packaging method 100 can be used to create multiple sealed air cavities on a wafer substrate and the compactness of the wafer level packaging method 100 results in an overall reduction of the die surface real estate required to form such multiple cavities. Further, as previously discussed, the completed packaging assembly is provided with a substantially low profile. Specifically, it has been determined that the process typically adds only the thickness of the sealing layer 234 to the height of the die, for example 30 microns. Further, this reliable and robust wafer level packaging method is versatile in that it is compatible with, and can withstand, solder ball (i.e. flip chip), wirebond applications, overmoulding processes, injection molding and other manufacturing processes without the need to utilize custom equipment. Finally, the wafer level packaging method 100 provides for cost effective, and readily produced wafer level packaging.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

1. A method for packaging a wafer segment within a packaging assembly, wherein the wafer segment has active and inactive areas, the method comprising:
a) providing a sacrificial layer over the active and inactive areas of the wafer segment;
b) modifying the sacrificial layer to create a sacrificial structure, wherein the sacrificial structure includes at least one sacrificial layer opening which exposes an inactive area of the wafer segment;
c) depositing a cover layer over the sacrificial structure, wherein the cover layer encloses the sacrificial structure and fills the at least one sacrificial layer opening;
d) modifying the cover layer to create a cover structure, wherein the cover structure has at least one cover layer opening, which exposes an inactive area of the wafer segment, and wherein the sacrificial structure can be removed through the at least one cover layer opening;
e) removing the sacrificial structure; and
f) enclosing the cover structure with a sealing layer, wherein the sealing layer fills the at least one cover layer opening in the cover structure and wherein the cover structure and the sealing layer form the packaging assembly for the wafer segment.

2. The method of claim 1, wherein the sacrificial layer includes a first sacrificial sublayer provided over the active and inactive areas of the wafer segment and a second sacrificial sublayer provided over the first sacrificial sublayer.

3. The method of claim 2, wherein the sacrificial structure including the at least one sacrificial layer opening is created by photo-patterning and removal techniques using a solvent where the second sacrificial sublayer is less susceptible than the first sublayer to the solvent such that the at least one sacrificial layer opening is formed with tapered walls.

4. The method of claim 3, wherein the cross sectional area of the sacrificial layer opening at the top of the sacrificial layer opening is larger than the cross sectional area of the sacrificial layer opening at the bottom of the sacrificial layer opening.

5. The method of claim 3, wherein the cover layer fills the at least one sacrificial layer opening to create at least one cover layer support element such that the at least one cover layer support element also has tapered walls.

6. The method of claim 5, wherein the cross sectional area of the cover layer support element at the top of the cover layer support element is larger than the cross sectional area of the cover layer support element at the bottom of the cover layer support element.

7. The method of claim 1, wherein the cover layer fills the at least one sacrificial layer opening to create at least one cover layer support element for the packaging assembly.

8. The method of claim 1, wherein the sealing layer flows through the at least one cover layer opening in the cover structure and forms at least one sealing layer support element for the packaging assembly.

9. The method of claim 1, wherein the cover layer fills the at least one sacrificial layer opening to create at least one cover layer support element for the packaging assembly and wherein the sealing layer flows through the at least one cover layer opening in the cover structure to form a sealing layer support element for the packaging assembly and wherein the sealing layer, the at least one sealing layer support element, the cover layer, and the at least one cover layer support element together define a packaging assembly having at least one sealed air cavity formed above at least one active area of the wafer segment.

10. The method of claim 8, wherein the at least one sealed air cavity is substantially hermetically sealed.

11. The method of claim 8, wherein each sealed air cavity is enclosed by the cover layer formed above and on its sides by cover layer support elements and sealing layer support elements.

12. The method of claim 10, wherein the cover layer support elements and sealing layer support elements are arranged in an alternating matter within the packaging assembly such that each sealed air cavity is enclosed by a cover layer support element on one side and a sealing layer support element on an opposite side.

13. The method of claim 8, wherein the wafer segment includes a wafer substrate and wherein each active area of the wafer substrate includes at least one device element mounted on the wafer substrate.

14. The method of claim 12, wherein the device element is associated with one of a micromechanical and an electromechanical device.

15. The method of claim 1, wherein the sealing layer adheres to the inactive areas of the wafer segment and to the cover structure.

16. The method of claim 1, wherein the sealing layer is a photosensitive controlled-flow epoxy film.

17. The method of claim 1, further comprising hardening the cover layer.

18. A wafer level packaging assembly for packaging a wafer segment, wherein the wafer segment has active and inactive areas, the assembly comprising:
a) a cover layer positioned over the wafer segment, said cover layer having at least one cover layer support element and at least one cover layer opening; and
b) a sealing layer having at least one sealing layer support element that fills one of the at least one cover layer opening such that the cover structure, the cover layer support element, the sealing layer and the sealing layer support element together define at least one sealed air cavity formed above at least one active area of the wafer segment.

19. The assembly of claim 18, wherein the at least one sealing layer support element adheres to the inactive areas of the device and to the cover structure, including the cover layer support elements.

20. The assembly of claim 10, wherein the at least one sealed air cavity is substantially hermetically sealed.

21. The assembly of claim 18, wherein each cover layer support element has tapered walls.

22. The assembly of claim 18, wherein the cross sectional area of the cover layer support element at the top of the cover layer support element is larger than the cross sectional area of the cover layer support element at the bottom of the cover layer support element.

23. The assembly of claim 18, wherein the sealing layer is a photosensitive controlled-flow epoxy film.

24. The assembly of claim 18, wherein the wafer segment includes a wafer substrate and wherein each active area of the wafer substrate includes at least one device element mounted on the wafer substrate.

25. The assembly of claim 24, wherein the device element is associated with one of a micromechanical and an electromechanical device.

26. The assembly of claim 18, wherein the at least one sealed air cavity is substantially hermetically sealed.

27. The assembly of claim 18, wherein each sealed air cavity is enclosed by the cover layer formed above and on its sides by cover layer support elements and sealing layer support elements.

28. The assembly of claim 27, wherein the cover layer support elements and sealing layer support elements are arranged in an alternating matter within the packaging assembly such that each sealed air cavity is enclosed by a cover layer support element on one side and a sealing layer support element on an opposite side.
